(19) United States
(12) Patent Application Publication
(10) Pub. No.: US 2019/0363174 A1
(43) Pub. Date: Nov. 28, 2019

(54) TRANSISTORS HAVING DOUBLE SPACERS AT TOPS OF GATE CONDUCTORS

(71) Applicant: GLOBALFOUNDRIES INC., GRAND CAYMAN (KY)

(72) Inventors: Hui Zang, Guilderland, NY (US); Ruilong Xie, Schenectady, NY (US); Jiehui Shu, Clifton Park, NY (US); Shesh Mani Pandey, Saratoga Springs, NY (US); Laertis Economikos, Wappingers Falls, NY (US)

(73) Assignee: GLOBALFOUNDRIES INC., GRAND CAYMAN (KY)

(21) Appl. No.: 15/987,957

(22) Filed: May 24, 2018

(51) Int. Cl. H01L 29/66; H01L 29/78; H01L 21/768

(52) U.S. Cl. CPC H01L 29/6656; H01L 29/66575; H01L 21/76897; H01L 29/66795; H01L 29/785

(57) ABSTRACT

Methods form transistor devices that have source/drain regions in a layer separated by a channel region. A gate conductor is above the channel region and has sidewalls extending from the top surface of the layer. First spacers are formed to contact the sidewalls of the gate conductor. The first spacers are formed to have top portions that are relatively distal to the surface of the layer, and bottom portions that are relatively adjacent to the surface of the layer. Second spacers are formed to contact the top portions of the first spacer. Conductive contacts are formed to connect to the source/drain regions. The bottom portions of the first spacers are formed to contact and be between the conductive contacts and the gate conductor. The second spacers are formed between the top portions of the first spacers and the conductive contacts.

### BACKGROUND

### Field of the Invention

The present disclosure relates to transistors, and more specifically, to insulating spacers formed on sidewalls of gate conductors of such transistors.

### Description of Related Art

Integrated circuit devices use transistors for many different functions, and these transistors can take many different forms, from planar transistors, to transistors that use a “fin” style structure. A fin of a fin-type transistor is a thin, long, six-sided rectangle that extends from a substrate, with sides that are longer than they are wide, a top and bottom that have the same length as the sides (but that have a width that is much more narrow), and ends that are as tall from the substrate as the width of the sides, but that are only as wide as the as the top and bottom.

To allow smaller transistor devices to be formed, processing can use the sidewalls of such fins, which are gates (dummy gates and/or gate conductors), to self-align other structures. Often insulating spacers are formed along the sidewalls of the gates. However, as different materials are added and removed for such self-aligned processing, areas (especially the top areas) of the sidewall spacers can be undesirably removed. If enough of the sidewall spacers is removed/destroyed, this can result in defect causing shorts between the gate conductors and other structures, such as source/drain conductive contacts.

### SUMMARY

Various methods herein form (e.g., epitaxially grow) source/drain regions in a layer (potentially with dummy gates in place), where the areas of the layer between the source/drain regions are semiconductor doped channel regions. These methods form gate insulators and gate conductors that are aligned with (above) the channel regions. The gate conductors have sidewalls extending from the top surface of the layer. These methods form first spacers on the sidewalls of the gate conductors. The sidewalls extend from the top surface of the layer.

Additionally, such methods form a sacrificial layer on the first spacers, and remove the sacrificial layer from only the top portions of the first spacers (the top portions of the first spacers are relatively distal to the top surface of the layer). Further, these methods form second spacers on the exposed top portions of the first spacers. The second spacers are only formed on the top portions of the first spacers that are above areas of the layer adjacent the source/drain regions (e.g., the second spacers are formed only in the active areas). The process of removing the sacrificial layer from the top portions of the first spacers thins the first spacers, but the second spacers compensate for such thinning of the top portions of the first spacers.

The first spacers and the second spacers are insulators (and can be formed of the same or different insulating materials). The top portions of the first spacers and the second spacers combine as relatively thicker insulators along top portions of the sidewalls of the gate conductors that are relatively distal to the top surface of the layer, and the bottom portions of the first spacers are corresponding relatively thinner insulators along bottom portions of the sidewalls of the gate conductors that are relatively adjacent to the top surface of the layer.

After this, these methods remove the sacrificial layer from the bottom portions of the first spacers (the bottom portions of the first spacers are relatively adjacent to the top surface of the layer). Then, such methods form conductive contacts that connect to the source/drain regions. The bottom portions of the first spacers are between the conductive contacts and the gate conductors, and the second spacers are between the top portions of the first spacers and the conductive contacts.

Various transistor devices herein include (among other components) a layer (e.g., substrate) having a channel region doped as a semiconductor, and a gate insulator on the top surface of the layer adjacent the channel region. Source/drain regions (e.g., epitaxially grown regions) are in the layer on opposite sides of the channel region. The source/drain regions are doped to be more electrically conductive relative to the channel region. Also, a gate conductor is aligned with (above) the channel region and contacts the gate insulator. The gate conductor has sidewalls extending from the top surface of the layer. An insulating cap contacts the top of the gate conductor (the top of the gate conductor is between the distal ends of the sidewalls of the gate conductor).

Additionally, first spacers contact the sidewalls of the gate conductor. The first spacers have top portions that are relatively distal to the top surface of the layer, and bottom portions that are relatively adjacent to the top surface of the layer. Such structures also include second spacers that make contact with the top portions of the first spacer, and not the bottom portions of the first spacers. The second spacers are only located on upper sections of the first spacers that extend from areas of the layer adjacent the source/drain regions (e.g., the second spacers are only in the active areas).

Further, conductive contacts are connected to the source/drain regions. The bottom portions of the first spacers are between the conductive contacts and the gate conductor. The second spacers are between the top portions of the first spacers and the conductive contacts. Therefore, the second spacers just make contact with the top portions of the first spacer, and not the bottom portions of the first spacers.

The top portions of the first spacers are relatively thinner than the bottom portions of the first spacers. The first spacers and the second spacers are insulators (but can be made of different insulating materials). Further, the top portions of the first spacers and the second spacers combine as relatively thicker insulators along top portions of the sidewalls of the gate conductors (the top portions of the sidewalls of the gate conductors are relatively distal to the top surface of the layer) and the bottom portions of the first spacers are corresponding relatively thinner insulators along bottom portions of the sidewalls of the gate conductors (the bottom portions of the sidewalls of the gate conductors are relatively adjacent to the top surface of the layer).

### BRIEF DESCRIPTION OF THE DRAWINGS

The embodiments herein will be better understood from the following detailed description with reference to the drawings, which are not necessarily drawn to scale and in which:

FIG. 1 is a conceptual schematic diagram illustrating a top view of integrated circuit devices according to embodiments herein;

FIG. 2 is a conceptual schematic diagram illustrating a cross-sectional view of isolation regions of the integrated circuit devices shown in FIG. 1;

FIGS. 3-11 are conceptual schematic diagrams illustrating a cross-sectional view of active regions of the integrated circuit devices shown in FIG. 1; and

FIG. 12 is a flow diagram illustrating embodiments herein.

### DETAILED DESCRIPTION

As mentioned above, as different materials are added and removed for self-aligned transistor formation processing, areas of the sidewall spacers (especially the top areas) can be undesirably removed. If enough of the sidewall spacers is removed/destroyed, this can result in defect causing shorts between the gate conductors and other structures, such as source/drain conductive contacts.

The systems and methods herein address these issues by providing double spacers (first and second spacers) only along the tops of the gate sidewalls, with single spacers along the bottoms of the gate sidewalls. Such double spacers compensate for thinning of the top portions of the first spacers. Thus, the top portions of the first spacers and the second spacers combine as relatively thicker double spacers along top portions of the sidewalls of the gate conductors, and the bottom portions of the first spacers are corresponding relatively thinner insulators along bottom portions of the sidewalls of the gate conductors. This prevents short circuits from occurring between the gate conductors and the conductive contacts that are sometimes caused by the thinning of the tops of the first spacers. However, because the second spacers are only formed along the tops of the first spacers, and not along the bottoms of the first spacers, sufficient room is left between gate conductors to land the conductive contacts on the source/drain regions.

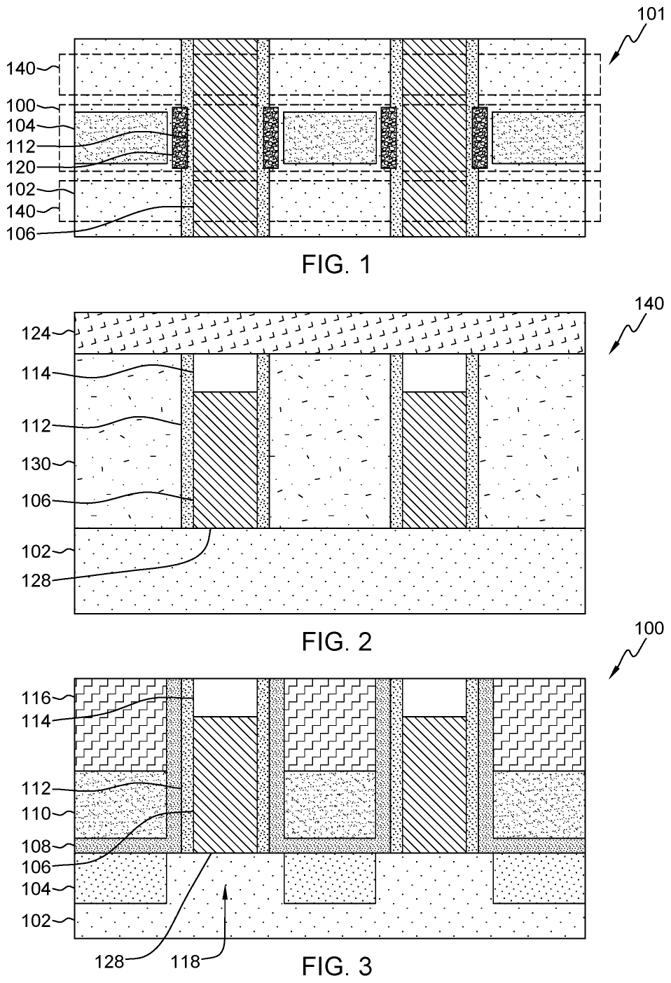

In greater detail, the above is conceptually illustrated in FIGS. 1-11. FIG. 1 illustrates a top (plan) conceptual view of different regions of an integrated circuit structure 101. Specifically, FIG. 1 illustrates isolation regions 140 with an active region 100 between each of the pairs of isolation regions on a substrate, such as a layer 102. Some of the components that make up transistors are located within the active region 100, including source/drain regions 104 between gate conductors 106, and spacers 112, 120 on the sidewalls of the gate conductors 106. FIG. 2 illustrates one of the isolation regions 140 in cross-section relative to the view shown in FIG. 1, and FIGS. 3-11 show the active area 100 in cross-section relative to the view shown in FIG. 1.

Thus, FIG. 2 illustrates one of the isolation regions 140 in cross-section relative to the view shown in FIG. 1 that includes portions of the gate conductors 106 with first spacers 112 formed thereon. The isolation regions 140 are processed to form a gate insulator 128 (e.g., an oxide, etc.), gate conductor 106, and protective cap 114 (e.g. nitride, etc.) within a trench formed between the spacers 112. Additionally, such structures are protected from the processing discussed below by protective layers, such as silicon carbon (SiC) 130 and an oxide 124 (which are formed while a mask protects the active areas 100.

As shown in FIG. 3, the active area structures 100 disclosed herein can be formed using many different processes. The lower layer 102 can be a material such as silicon that has been grown, formed, or implanted to be a semiconductor. Sacrificial fins (dummy gates, not shown) are previously formed/patterned on the gate insulator 128. Insulator spacers 112 (sometimes referred to herein as first spacers) are deposited/grown on the dummy gates, and then the existing structures are used to self-align the source/drain regions 104 that can be implanted or epitaxially grown in the layer 102. Additional sacrificial layers, such as a deposited conformal insulator 108, epitaxially grown silicon layers 110, insulator layers (e.g., oxides or other insulators) 116, etc., are formed and the dummy gates are removed and replaced with gate insulators 128 and gate conductors 106 (metal, polysilicon, etc.) capped by caps 114 (nitride, etc.). This forms transistor structures, where the areas of the layer 102 between the source/drain regions 104 are semiconductor doped channel regions 118, and voltage in the gate conductors 106 alters the conductivity of the channel regions 118 when the structures are used as field effect transistors (FETs).

Thus, as shown in FIG. 3, the methods herein form such gate insulators 128 and gate conductors 106 that are aligned with (above) the channel regions 118 of the layer 102. These processes also form the gate conductors 106 to have sidewalls extending from (e.g., approximately (meaning within 5%, 10%, 25%) perpendicular to) the top surface of the layer 102. The top surface (or what is sometimes simply referred to herein as “surface”) of the layer 102 is where the gate insulators 128 are located. Thus, these methods form first spacers 112 on the full vertical length of the sidewalls of the gate conductors 106, and such gate sidewalls and first spacers 112 extend from the top surface of the layer 102 to the top (most distal point) of the gate conductors 106.

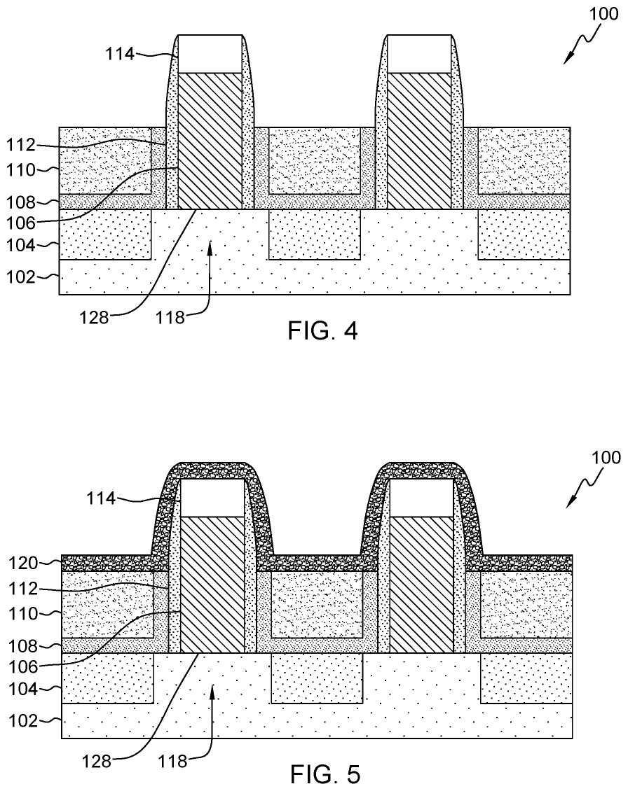

Additionally, as noted above, such methods form one or more elements that combine into a sacrificial structure/layer 108, 110, 116 on the first spacers 112. As shown in FIG. 4, processing herein removes a portion of the sacrificial layer (all of the oxide 116 and the upper portion of the conformal layer 108) from only the top portions (e.g., top quarter, top third, top half, etc.) of the first spacers 112. The top (upper) portions of the first spacers 112 are those portions that are relatively distal to (furthest away from) the top surface of the layer 102. This step uses processing that selectively attacks the oxide 116 and conformal layer 108 (potentially in separate steps), but does not substantially affect the silicon material 110, such as anisotropic reactive ion etching (RIE). While, such anisotropic RIE generally attacks horizontal surfaces (those parallel to the top surface of the layer 102) at a faster rate relative to vertical surfaces (that are perpendicular to the horizontal surfaces), there is often thinning that occurs more on portions of the first spacer 112 that are further away from the silicon layer 110, as shown in FIG. 4.

As shown in FIG. 5, such methods then form insulator material (e.g., SiN/SiC/SiCO, etc.) for second spacers 120 on the exposed top portions of the first spacers 112. More specifically, the material for the second spacers 120 can be formed using conformal deposition/growth, etc., processing. The first spacers 112 and the second spacers 120 are insulators (and can be formed of the same or different insulating materials, such as low-k insulators, etc.).

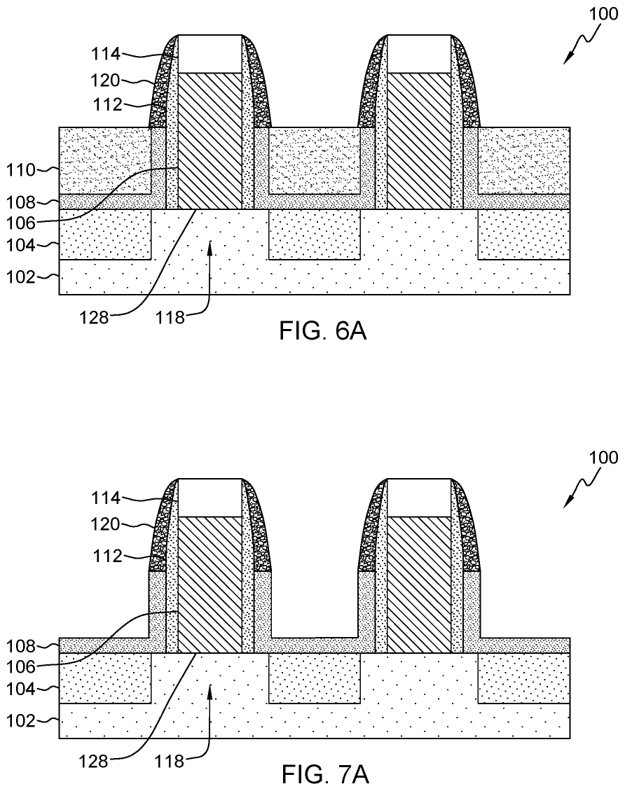

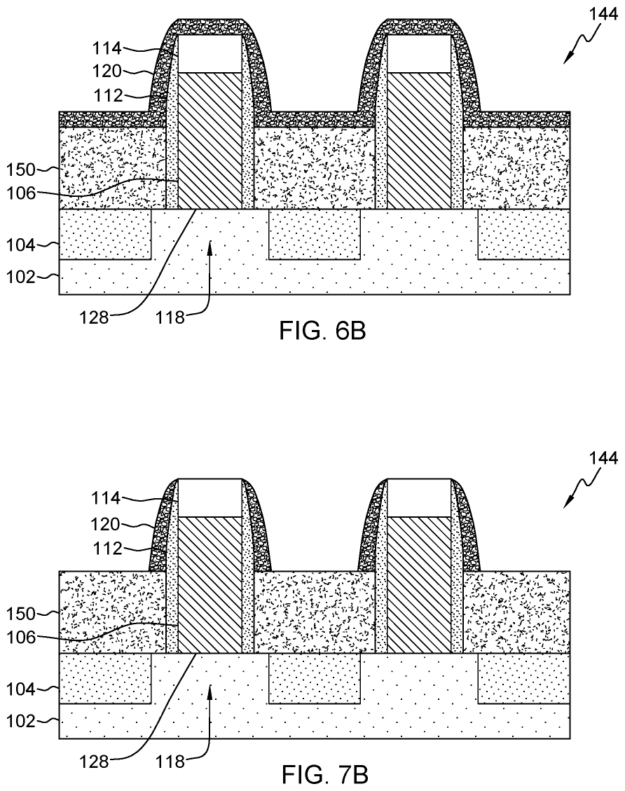

As shown in FIG. 6A, anisotropic processing is again used to remove the second spacers 120 from horizontal surfaces, leaving the second spacers 120 only on the top portions of the first spacers 112. Also, note that as shown in FIG. 1 discussed above, the second spacers 120 are formed only in the active areas 100 because the isolation areas 140 are protected by layers 124, 130 during the processing shown in FIGS. 3-11. Also, in FIG. 7A, the silicon layer 110 can be removed (e.g., using wet removal processes, etc.).

FIGS. 6B-7B illustrate similar processing to that shown in FIGS. 6A-7A; however, in FIGS. 6B-7B, rather than the conformal layer 108 and silicon layer 110, instead a different transistor structure 144 is shown that uses an organic dielectric layer (ODL) 150 to protect the bottom portions of the first spacers 112, while the second spacer material 120 is formed (FIG. 6B) and then subsequently removed from horizontal surfaces (FIG. 7B).

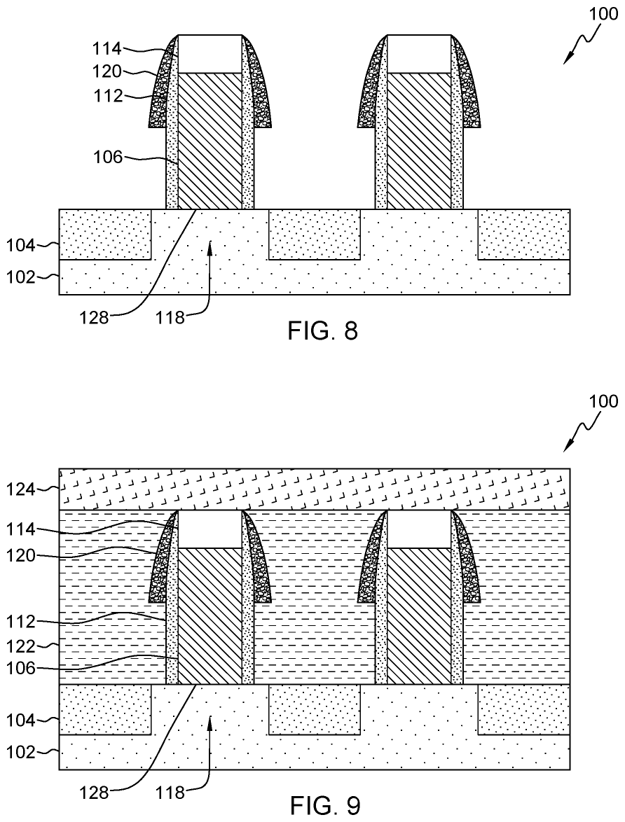

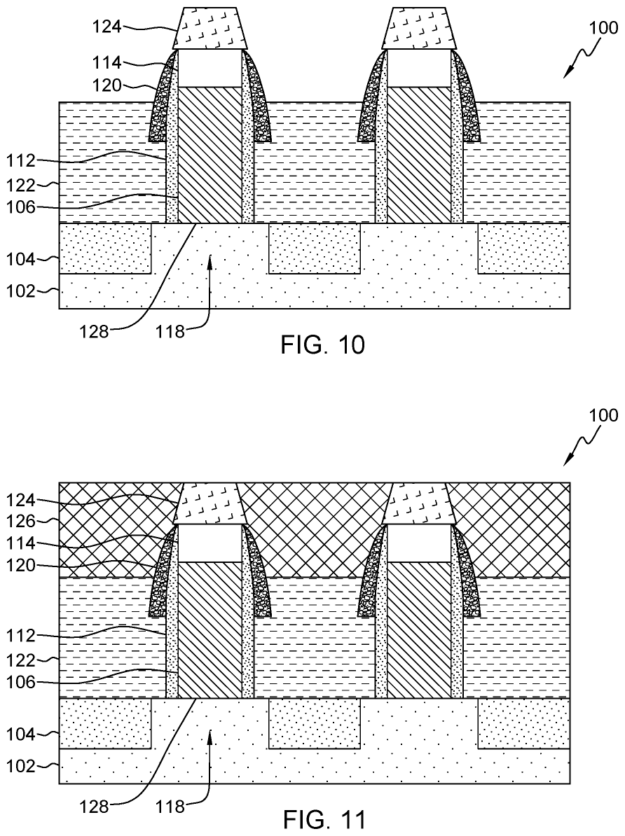

Regardless of whether processing in FIGS. 6A-7A or processing in FIGS. 6B-7B is utilized, after this, these methods remove any remaining sacrificial layer 108 or 150 from the bottom portions of the first spacers 112 (the bottom portions of the first spacers 112 are relatively adjacent to the top surface of the layer 102), leaving the structure shown in FIG. 8. Following this, as shown in FIG. 9, initial conductive contacts 122 are deposited to fill around the exposed structures shown in FIG. 8 and to contact the source/drain regions 104, and a protective insulating structure 124 (e.g., an oxide, etc.) can then be formed.

As shown in FIG. 10, the initial conductive contacts 122 can be reduced in height in processing (e.g., time controlled etching, etc.) that leaves the protective structure 124 only on the caps 114. Note that this processing can sometimes slightly (e.g., less than 25%) reduce the thickness of the second spacers 120. Then, as shown in FIG. 11, additional conductive material 126 (that can be the same or different from the initial conductive contacts 122) is deposited to provide complete electrical contacts, through any overlying inter-layer dielectric (ILD) structures, to the source/drain regions 104. Thus, such methods form conductive contacts 122, 126 that connect to the source/drain regions 104. The bottom portions of the first spacers 112 are between the conductive contacts 122, 126 and the gate conductors 106; while, in contrast, the second spacers 120 are between the top portions of the first spacers 112 and the conductive contacts 122, 126.

As stated above, the process of removing the sacrificial layer from the top portions of the first spacers 112 thins the first spacers 112, but the second spacers 120 compensate for such thinning of the top portions of the first spacers 112 (even if such second spacers 120 are slightly thinned during the formation of the conductive contacts 122, 126 shown in FIG. 10). Thus, the top portions of the first spacers 112 and the second spacers 120 combine as relatively thicker insulators along top portions of the sidewalls of the gate conductors 106 (that are relatively distal to the top surface of the layer 102) and the bottom portions of the first spacers 112 are relatively thinner insulators along bottom portions of the sidewalls of the gate conductors 106 (that are relatively adjacent to the top surface of the layer 102). This prevents short circuits from occurring between the gate conductors 106 and the conductive contacts 122, 126 that are sometimes caused by the thinning of the tops of the first spacers 112. However, because the second spacers 120 are only formed along the tops of the first spacers 112 and not along the bottoms of the first spacers 112, sufficient room is left to land the conductive contacts 122, 126 on the source/drain regions 104.

Therefore, as shown in FIG. 11, such processing produces transistor devices 100 that include (among other components) a layer 102 (e.g., flat planar substrate) having a channel region 118 doped as a semiconductor, and a gate insulator 128 on the top surface of the layer 102 adjacent the channel region 118. Source/drain regions 104 (e.g., epitaxially grown regions) are in the layer 102 on opposite sides of the channel region 118. The source/drain regions 104 are doped to be more electrically conductive relative to the channel region 118. Also, a gate conductor 106 is aligned with (above) the channel region 118 and contacts the gate insulator 128. The gate conductor 106 has sidewalls extending from the top surface of the layer 102. An insulating cap 114 contacts the top of the gate conductor 106 (the top of the gate conductor 106 is between the distal ends of the sidewalls of the gate conductor 106).

Additionally, first spacers 112 are immediately laterally adjacent to and contact the sidewalls of the gate conductor 106. The first spacers 112 have top portions (e.g., top 30%, 50%, 70%, etc. of the first spacers 112) that are relatively distal to the top surface of the layer 102, and bottom portions (e.g., bottom 30%, 50%, 70%, etc. of the first spacers 112) that are relatively adjacent to the top surface of the layer 102. Such structures also include second spacers 120 that are immediately laterally adjacent to and make contact with only the top portions of the first spacers 112, and not the bottom portions of the first spacers 112. The second spacers 120 are only located on upper sections of the first spacers 112 that extend from (e.g., approximately (meaning within 5%, 10%, 25%) perpendicular to) areas of the layer 102 adjacent the source/drain regions 104 (e.g., the second spacers 120 are only in the active areas, see FIG. 1).

Further, conductive contacts 122, 126 are laterally adjacent to the gate conductors 106 and the sidewall spacers 112, 120, and are connected to the source/drain regions 104. The bottom portions of the first spacers 112 are between the conductive contacts 122, 126 and the gate conductor 106. The second spacers 120 are between the top portions of the first spacers 112 and the conductive contacts 122, 126. Therefore, the second spacers 120 just make contact with the top portions of the first spacers 112, and not the bottom portions of the first spacers 112.

The top portions of the first spacers 112 are relatively thinner than the bottom portions of the first spacers 112. The first spacers 112 and the second spacers 120 are insulators (but can be made of different insulating materials). Further, the top portions of the first spacers 112 and the second spacers 120 combine as relatively thicker insulators along top portions of the sidewalls of the gate conductor 106 (the top portions of the sidewalls of the gate conductor 106 are relatively distal to the top surface of the layer 102) and the bottom portions of the first spacers 112 are relatively thinner insulators along bottom portions of the sidewalls of the gate conductor 106 (the bottom portions of the sidewalls of the gate conductor 106 are relatively adjacent to the top surface of the layer 102).

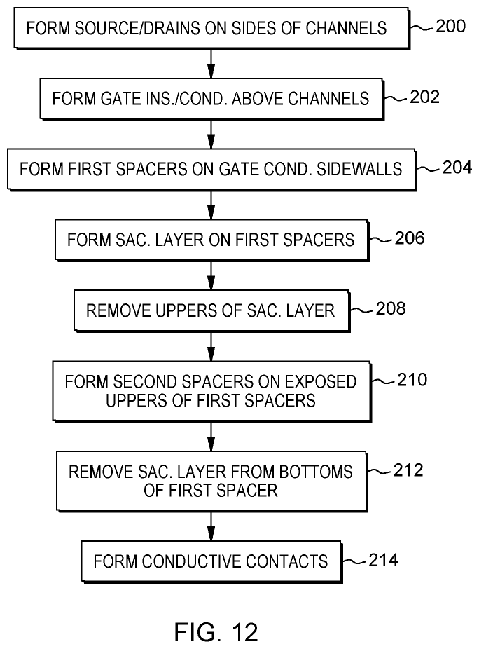

FIG. 12 shows such processing in flowchart form. More specifically, in item 200, such methods herein form (e.g., epitaxially grow) source/drain regions in a layer, where the areas of the layer between the source/drain regions are semiconductor doped channel regions. In item 202, these methods form gate insulators and gate conductors that are aligned with (above) the channel regions. The gate conductors have sidewalls extending from the top surface of the layer. These methods form first spacers on the sidewalls of the gate conductors in item 204. The sidewalls extend from the top surface of the layer.

Additionally, in item 206, such methods form a sacrificial layer on the first spacers, and remove the sacrificial layer from only the top portions of the first spacers (the top portions of the first spacers are relatively distal to the top surface of the layer) in item 208. Further, such methods form second spacers on the exposed top portions of the first spacers in item 210. The second spacers are only formed in item 210 on upper sections of the first spacers above areas of the layer adjacent the source/drain regions (e.g., the second spacers are formed only in the active areas). The process of removing the sacrificial layer from the top portions of the first spacers in item 208 thins the first spacers, but the second spacers formed in item 210 compensate for such thinning of the top portions of the first spacers.

The first spacers and the second spacers are insulators (and can be formed of the same or different insulating materials). The top portions of the first spacers and the second spacers combine as relatively thicker insulators along top portions of the sidewalls of the gate conductors that are relatively distal to the top surface of the layer, and the bottom portions of the first spacers are relatively thinner insulators along bottom portions of the sidewalls of the gate conductors that are relatively adjacent to the top surface of the layer.

After this, in item 212, these methods remove the sacrificial layer from the bottom portions of the first spacers (the bottom portions of the first spacers are relatively adjacent to the top surface of the layer). Then, in item 214, such methods form conductive contacts that connect to the source/drain regions. The bottom portions of the first spacers are between the conductive contacts and the gate conductors, and the second spacers are between the top portions of the first spacers and the conductive contacts.

For purposes herein, a “semiconductor” is a material or structure that may include an implanted or in situ (e.g., epitaxially grown) impurity that allows the material to sometimes be a conductor and sometimes be an insulator, based on electron and hole carrier concentration. As used herein, “implantation processes” can take any appropriate form (whether now known or developed in the future) and can be, for example, ion implantation, etc. Epitaxial growth occurs in a heated (and sometimes pressurized) environment that is rich with a gas of the material that is to be grown.

For purposes herein, an “insulator” is a relative term that means a material or structure that allows substantially less (<95%) electrical current to flow than does a “conductor.” The dielectrics (insulators) mentioned herein can, for example, be grown from either a dry oxygen ambient or steam and then patterned. Alternatively, the dielectrics herein may be formed from any of the many candidate high dielectric constant (high-k) materials, including but not limited to silicon nitride, silicon oxynitride, a gate dielectric stack of SiO₂ and Si₃N₄, and metal oxides like tantalum oxide. The thickness of dielectrics herein may vary contingent upon the required device performance.

The conductors mentioned herein can be formed of any conductive material, such as polycrystalline silicon (polysilicon), amorphous silicon, a combination of amorphous silicon and polysilicon, and polysilicon-germanium, rendered conductive by the presence of a suitable dopant. Alternatively, the conductors herein may be one or more metals, such as tungsten, hafnium, tantalum, molybdenum, titanium, or nickel, or a metal silicide, any alloys of such metals, and may be deposited using physical vapor deposition, chemical vapor deposition, or any other technique known in the art.

There are various types of transistors, which have slight differences in how they are used in a circuit. For example, a bipolar transistor has terminals labeled base, collector, and emitter. A small current at the base terminal (that is, flowing between the base and the emitter) can control, or switch, a much larger current between the collector and emitter terminals. Another example is a field-effect transistor, which has terminals labeled gate, source, and drain. A voltage at the gate can control a current between source and drain. Within such transistors, a semiconductor (channel region) is positioned between the conductive source region and the similarly conductive drain (or conductive source/emitter regions), and when the semiconductor is in a conductive state, the semiconductor allows electrical current to flow between the source and drain, or collector and emitter. The gate is a conductive element that is electrically separated from the semiconductor by a “gate oxide” (which is an insulator); and current/voltage within the gate changes makes the channel region conductive, allowing electrical current to flow between the source and drain. Similarly, current flowing between the base and the emitter makes the semiconductor conductive, allowing current to flow between the collector and emitter.

A positive-type transistor “P-type transistor” uses impurities such as boron, aluminum or gallium, etc., within an intrinsic semiconductor substrate (to create deficiencies of valence electrons) as a semiconductor region. Similarly, an “N-type transistor” is a negative-type transistor that uses impurities such as antimony, arsenic or phosphorous, etc., within an intrinsic semiconductor substrate (to create excessive valence electrons) as a semiconductor region.

Generally, transistor structures are formed by depositing or implanting impurities into a substrate to form at least one semiconductor channel region, bordered by shallow trench isolation regions below the top (upper) surface of the substrate. A “substrate” herein can be any material appropriate for the given purpose (whether now known or developed in the future) and can be, for example, silicon-based wafers (bulk materials), ceramic materials, organic materials, oxide materials, nitride materials, etc., whether doped or undoped. The “shallow trench isolation” (STI) structures are generally formed by patterning openings/trenches within the substrate and growing or filling the openings with a highly insulating material (this allows different active areas of the substrate to be electrically isolated from one another).

A hardmask can be formed of any suitable material, whether now known or developed in the future, such as a nitride, metal, or organic hardmask, that has a hardness greater than the substrate and insulator materials used in the remainder of the structure.

When patterning any material herein, the material to be patterned can be grown or deposited in any known manner and a patterning layer (such as an organic photoresist) can be formed over the material. The patterning layer (resist) can be exposed to some pattern of light radiation (e.g., patterned exposure, laser exposure, etc.) provided in a light exposure pattern, and then the resist is developed using a chemical agent. This process changes the physical characteristics of the portion of the resist that was exposed to the light. Then one portion of the resist can be rinsed off, leaving the other portion of the resist to protect the material to be patterned (which portion of the resist that is rinsed off depends upon whether the resist is a negative resist (illuminated portions remain) or positive resist (illuminated portions are rinsed off). A material removal process is then performed (e.g., wet etching, anisotropic etching (orientation dependent etching), plasma etching (reactive ion etching (RIE), etc.)) to remove the unprotected portions of the material below the resist to be patterned. The resist is subsequently removed to leave the underlying material patterned according to the light exposure pattern (or a negative image thereof).

For purposes herein, “sidewall spacers” are structures that are well-known to those ordinarily skilled in the art and are generally formed by depositing or growing a conformal insulating layer (such as any of the insulators mentioned above) and then performing a directional etching process (anisotropic) that etches material from horizontal surfaces at a greater rate than its removes material from vertical surfaces, thereby leaving insulating material along the vertical sidewalls of structures. This material left on the vertical sidewalls is referred to as sidewall spacers.

While only one or a limited number of transistors are illustrated in the drawings, those ordinarily skilled in the art would understand that many different types transistor could be simultaneously formed with the embodiment herein and the drawings are intended to show simultaneous formation of multiple different types of transistors; however, the drawings have been simplified to only show a limited number of transistors for clarity and to allow the reader to more easily recognize the different features illustrated. This is not intended to limit this disclosure because, as would be understood by those ordinarily skilled in the art, this disclosure is applicable to structures that include many of each type of transistor shown in the drawings.

The flowchart and block diagrams in the figures illustrate the architecture, functionality, and operation of possible implementations of devices and methods according to various embodiments. In this regard, each block in the flowchart or block diagrams may represent a module, segment, or portion of instructions, which includes one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the foregoing. As used herein, the singular forms “a,” “an,” and “the” are intended to include the plural forms as well, unless the context clearly indicates otherwise. Furthermore, as used herein, terms such as “right”, “left”, “vertical”, “horizontal”, “top”, “bottom”, “upper”, “lower”, “under”, “below”, “underlying”, “over”, “overlying”, “parallel”, “perpendicular”, etc., are intended to describe relative locations as they are oriented and illustrated in the drawings (unless otherwise indicated) and terms such as “touching”, “in direct contact”, “abutting”, “directly adjacent to”, “immediately adjacent to”, etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element.

Embodiments herein may be used in a variety of electronic applications, including but not limited to advanced sensors, memory/data storage, semiconductors, microprocessors and other applications. A resulting device and structure, such as an integrated circuit (IC) chip can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The description of the present embodiments has been presented for purposes of illustration and description, but is not intended to be exhaustive or limited to the embodiments in the form disclosed. Many modifications and variations will be apparent to those of ordinary skill in the art without departing from the scope and spirit of the embodiments herein. The embodiments were chosen and described in order to best explain the principles of such, and the practical application, and to enable others of ordinary skill in the art to understand the various embodiments with various modifications as are suited to the particular use contemplated.

While the foregoing has been described in detail in connection with only a limited number of embodiments, it should be readily understood that the embodiments herein are not limited to such disclosure. Rather, the elements herein can be modified to incorporate any number of variations, alterations, substitutions or equivalent arrangements not heretofore described, but which are commensurate with the spirit and scope herein. Additionally, while various embodiments have been described, it is to be understood that aspects herein may be included by only some of the described embodiments. Accordingly, the claims below are not to be seen as limited by the foregoing description. A reference to an element in the singular is not intended to mean “one and only one” unless specifically stated, but rather “one or more.” All structural and functional equivalents to the elements of the various embodiments described throughout this disclosure that are known or later, come to be known, to those of ordinary skill in the art are expressly incorporated herein by reference and intended to be encompassed by this disclosure. It is therefore to be understood that changes may be made in the particular embodiments disclosed which are within the scope of the foregoing as outlined by the appended claims.

1. A transistor device comprising:
a layer having a channel region;
source/drain regions in the layer adjacent the channel region;
a gate conductor above the channel region having sidewalls extending from a surface of the layer;
first spacers contacting the sidewalls of the gate conductor, wherein the first spacers have top portions that are relatively distal to the surface of the layer, and bottom portions that are relatively adjacent to the surface of the layer;
second spacers contacting the top portions of the first spacers; and
conductive contacts connected to the source/drain regions,
wherein the bottom portions of the first spacers physically contact and are between the conductive contacts and the gate conductor without other elements separating the bottom portions of the first spacers from the conductive contacts and the gate conductor, and
wherein the second spacers are between the top portions of the first spacers and the conductive contacts.

2. The transistor device according to claim 1, wherein the top portions of the first spacers are relatively thinner than the bottom portions of the first spacers.

3. The transistor device according to claim 1, wherein the second spacers are only formed on the top portions of the first spacers that extend from areas of the layer adjacent the source/drain regions.

4. The transistor device according to claim 1, wherein the first spacers and the second spacers are insulators.

5. The transistor device according to claim 4, wherein the top portions of the first spacers and the second spacers combine as relatively thicker insulators along top portions of the sidewalls of the gate conductor that are relatively distal to the surface of the layer, and the bottom portions of the first spacers are relatively thinner insulators along bottom portions of the sidewalls of the gate conductor that are relatively adjacent to the surface of the layer.

6. The transistor device according to claim 1, wherein the second spacers are positioned only along the top portions of the first spacers, and not along the bottom portions of the first spacers.

7. The transistor device according to claim 1, wherein the source/drain regions comprise epitaxially grown regions.

8. A transistor device comprising:
a layer having a channel region doped as a semiconductor;
a gate insulator on a top surface of the layer adjacent the channel region;
source/drain regions in the layer on opposite sides of the channel region, wherein the source/drain regions are doped to be more electrically conductive relative to the channel region;
a gate conductor above the channel region and contacting the gate insulator, wherein the gate conductor has sidewalls extending from the top surface of the layer;
an insulating cap contacting a top of the gate conductor, wherein the top of the gate conductor is between distal ends of the sidewalls of the gate conductor;
first spacers contacting the sidewalls of the gate conductor, wherein the first spacers have top portions that are relatively distal to the top surface of the layer, and bottom portions that are relatively adjacent to the top surface of the layer;
second spacers contacting the top portions of the first spacers; and
conductive contacts connected to the source/drain regions,
wherein the bottom portions of the first spacers physically contact and are between the conductive contacts and the gate conductor without other elements separating the bottom portions of the first spacers from the conductive contacts and the gate conductor, and
wherein the second spacers are between the top portions of the first spacers and the conductive contacts.

9. The transistor device according to claim 8, wherein the top portions of the first spacers are relatively thinner than the bottom portions of the first spacers.

10. The transistor device according to claim 8, wherein the second spacers are only formed on the top portions of the first spacers that extend from areas of the layer adjacent the source/drain regions.

11. The transistor device according to claim 8, wherein the first spacers and the second spacers are insulators.

12. The transistor device according to claim 11, wherein the top portions of the first spacers and the second spacers combine as relatively thicker insulators along top portions of the sidewalls of the gate conductor that are relatively distal to the top surface of the layer, and the bottom portions of the first spacers are relatively thinner insulators along bottom portions of the sidewalls of the gate conductors that are relatively adjacent to the top surface of the layer.

13. The transistor device according to claim 8, wherein the second spacers are positioned only along the top portions of the first spacers, and not along the bottom portions of the first spacers.

14. The transistor device according to claim 8, wherein the source/drain regions comprise epitaxially grown regions.

15-20. (canceled)

21. A transistor device comprising:
source/drain regions in a layer adjacent a channel region;
a gate conductor above the channel region;
first spacers contacting sidewalls of the gate conductor, wherein the first spacers have top portions, and bottom portions that are relatively adjacent to the layer;
conductive contacts connected to the source/drain regions, wherein the bottom portions of the first spacers physically contact and are between the conductive contacts and the gate conductor without other elements separating the bottom portions of the first spacers from the conductive contacts and the gate conductor; and
second spacers between the top portions of the first spacers and the conductive contacts.

22. The transistor device according to claim 21, wherein the top portions of the first spacers are relatively thinner than the bottom portions of the first spacers.

23. The transistor device according to claim 21, wherein the second spacers are only formed on the top portions of the first spacers that extend from areas of the layer adjacent the source/drain regions.

24. The transistor device according to claim 21, wherein the first spacers and the second spacers are insulators.

25. The transistor device according to claim 24, wherein the top portions of the first spacers and the second spacers combine as relatively thicker insulators along top portions of the sidewalls of the gate conductor that are relatively distal to a surface of the layer, and the bottom portions of the first spacers are relatively thinner insulators along bottom portions of the sidewalls of the gate conductor that are relatively adjacent to the surface of the layer.

26. The transistor device according to claim 21, wherein the second spacers are positioned only along the top portions of the first spacers, and not along the bottom portions of the first spacers.
